(19) United States
(12) Patent Application Publication
(10) Pub. No.: US 2012/0161309 A1
(43) Pub. Date: Jun. 28, 2012

(54) SEMICONDUCTOR PACKAGE

(75) Inventor: Hiromitsu UTSUMI, Tokyo (JP)

(73) Assignee: MITSUBISHI ELECTRIC CORPORATION, Tokyo (JP)

(21) Appl. No.: 13/179,665

(22) Filed: Jul. 11, 2011

(30) Foreign Application Priority Data
Dec. 28, 2010 (JP) 2010-292998

(51) Int. Cl. H01L 23/04; H01L 23/52

(52) U.S. Cl. 257/704; 257/734; 257/E23.141; 257/E23.181

(57) ABSTRACT

A semiconductor package includes a base portion including a first member and a second member which are joined to each other; a semiconductor element mounted on the first member; a terminal mounted on the second member; and a wire electrically connecting the semiconductor element to the terminal. Heat resistance of the first member is lower than heat resistance of the second member, and linear thermal expansion coefficient of the second member is smaller than linear thermal expansion coefficient of the first member.

### BACKGROUND OF THE INVENTION

1. Field of the Invention

The present invention relates to a semiconductor package which can secure heat dissipation properties and prevent the warpage of the base portion with thermal history.

2. Background Art

An air-tightly-sealed metal-base package is used as a semiconductor package (for example, refer to Japanese Patent Application Laid-Open No. 4-287950). To make transistors for amplification two stages in such a semiconductor package, the shape of the base portion to mount transistors is made to be a vertically long rectangle. To also improve the heat dissipation property of the transistor, the base portion is made thin.

### SUMMARY OF THE INVENTION

However, when the base portion becomes vertically long rectangular and becomes a thin plate, the base portion is easily warped with thermal history. Therefore, when a semiconductor package was mounted by screwing, stress was focused on the ceramic terminal to generate cracks, and there was the case wherein air tightness could not be maintained.

In view of the above-described problems, an object of the present invention is to provide a semiconductor package which can secure heat dissipation properties and prevent the warpage of the base portion with thermal history.

According to the present invention, a semiconductor package comprises: a base portion including a first member and a second member which are joined; a semiconductor element mounted on the first member; a terminal mounted on the second member; and a wire electrically connecting the semiconductor element and the terminal, wherein a heat resistance of the first member is lower than a heat resistance of the second member, and a linear expansion coefficient of the second member is smaller than a linear expansion coefficient of the first member.

The present invention makes it possible to secure heat dissipation properties and prevent the warpage of the base portion with thermal history.

Other and further objects, features and advantages of the invention will appear more fully from the following description.

### BRIEF DESCRIPTION OF THE DRAWINGS

FIG. 1 is a top view showing a semiconductor package according to the first embodiment of the present invention.

FIG. 2 is a sectional view taken along the line A-A′ in FIG. 1.

FIG. 3 is a top view showing a semiconductor package according to the comparative example.

FIG. 4 is a sectional view taken along the line B-B′ in FIG. 3.

FIG. 5 is a diagram showing the warpage of the base portion of the comparative example.

FIG. 6 is a bottom view showing a semiconductor package according to the second embodiment of the present invention.

FIG. 7 is a sectional view taken along the line C-C′ in FIG. 6.

FIG. 8 is a bottom view showing a semiconductor package according to the third embodiment of the present invention.

FIG. 9 is a top view showing a semiconductor package according to the fourth embodiment of the present invention.

FIG. 10 is a sectional view showing a semiconductor package according to the fifth embodiment of the present invention.

FIG. 11 is a sectional view showing a semiconductor package according to the sixth embodiment of the present invention.

### DETAILED DESCRIPTION OF THE PREFERRED EMBODIMENTS

A semiconductor package according to the embodiments of the present invention will be described with reference to the drawings. The same components will be denoted by the same symbols, and the repeated description thereof may be omitted.

### First Embodiment

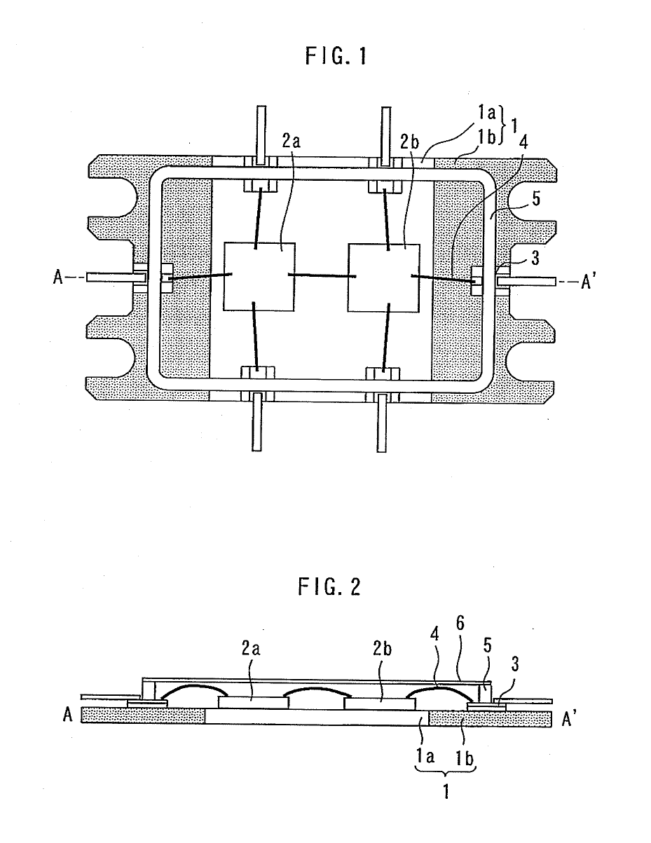

FIG. 1 is a top view showing a semiconductor package according to the first embodiment of the present invention. FIG. 2 is a sectional view taken along the line A-A′ in FIG. 1. The semiconductor package is a semiconductor amplifier used in a microwave band.

The base portion 1 is rectangular having short and long sides, and is a ply board wherein a first member 1a and second members 1b are joined in the long-side direction. Here, the first member 1a is composed of a Cu alloy, and the second members 1b are composed of kovar or CuW. Therefore, the heat resistance of the first member 1a is lower than the heat resistance of the second members 1b, and the linear expansion coefficient of the second members 1b is smaller than the linear expansion coefficient of the first member 1a.

On the first member 1a, two semiconductor elements 2a and 2b are collaterally mounted in the long-side direction. The semiconductor elements 2a and 2b are high-output internal consistency transistors for amplification. On the second members 1b, ceramic terminals 3 are mounted. The ceramic terminals 3 are ceramic plates whereon metal wirings are provided. Wires 4 electrically connect the semiconductor elements 2a and 2b, and the ceramic terminals 3. A side-wall member 5 is provided on the base portion 1 so as to surround the semiconductor elements 2a and 2b. A cap 6 is joined on the side-wall member 5 so as to cover the semiconductor elements 2a and 2b.

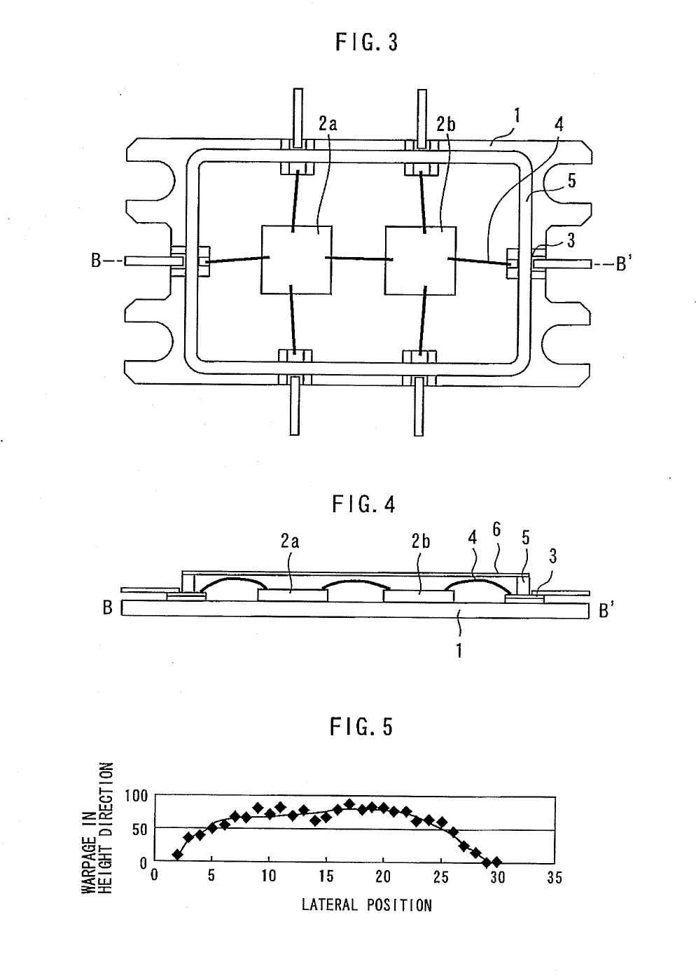

Next, the effect of the present embodiment will be described in comparison with the effect of a comparative example. FIG. 3 is a top view showing a semiconductor package according to the comparative example. FIG. 4 is a sectional view taken along the line B-B′ in FIG. 3. The base portion 1 of the comparative example is entirely composed of a Cu alloy. FIG. 5 is a diagram showing the warpage of the base portion of the comparative example. The comparative example has a problem wherein the base portion 1 is warped in the height direction with thermal history.

On the other hand, in the present embodiment, the warpage of the base portion 1 with thermal history can be prevented by mounting the ceramic terminal 3 on the second members 1b having a lower linear expansion coefficient. Furthermore, by mounting the semiconductor elements 2a and 2b on the first member 1a having a low thermal resistance, heat dissipation properties can be secured.

### Second Embodiment

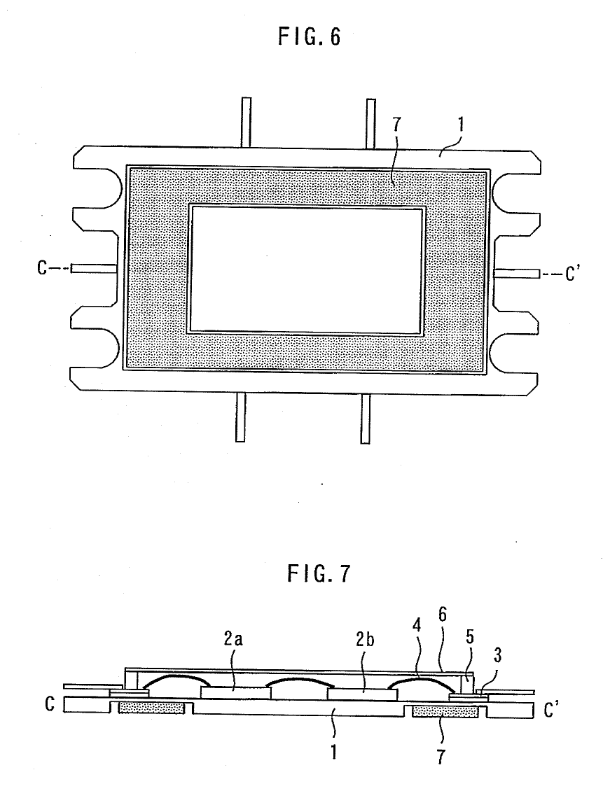

FIG. 6 is a bottom view showing a semiconductor package according to the second embodiment of the present invention. FIG. 7 is a sectional view taken along the line C-C′ in FIG. 6. A reinforcing member 7 is joined to the region of the base portion 1 where semiconductor elements 2a and 2b are not mounted. In the present embodiment, the reinforcing member 7 is joined to the bottom surface of the base portion 1 so as to surround the region of the base portion 1 where the semiconductor elements 2a and 2b are mounted. Here, the base portion 1 is composed of a Cu alloy, and the reinforcing member 7 is composed of kovar or CuW. Therefore, the heat resistance of the base portion 1 is lower than the heat resistance of the reinforcing member 7, and the linear expansion coefficient of the reinforcing member 7 is smaller than the coefficient linear of expansion of the base portion 1.

As described above, by reinforcing the base portion 1 with the reinforcing member 7 having a low linear expansion coefficient, the warpage of the base portion 1 with thermal history can be prevented. Furthermore, by mounting the semiconductor elements 2a and 2b,on portions of the base portion 1 where the reinforcing member 7 is not joined, heat dissipation properties can be secured.

### Third Embodiment

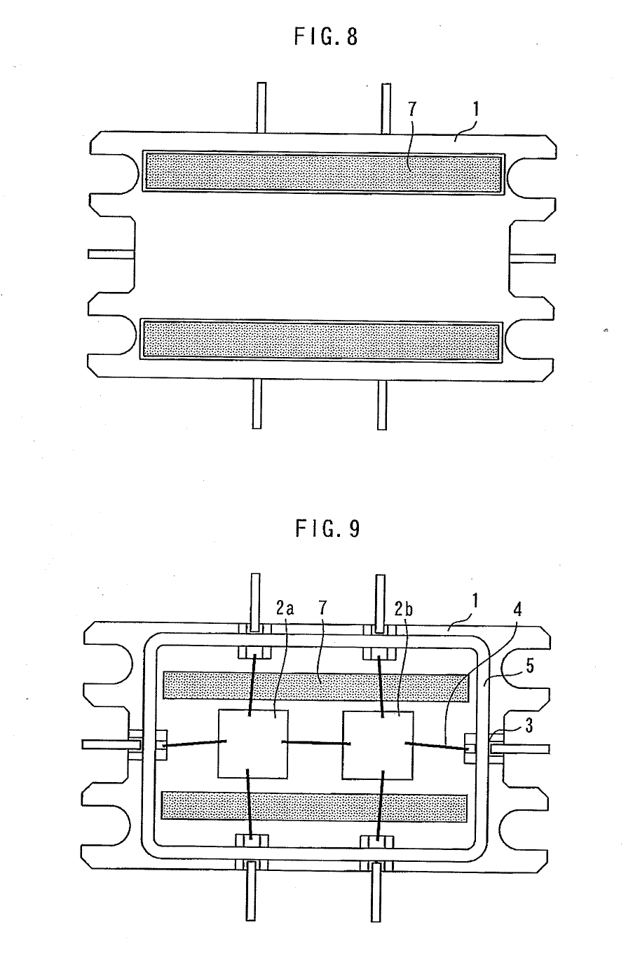

FIG. 8 is a bottom view showing a semiconductor package according to the third embodiment of the present invention. Reinforcing members 7 are joined to the region of the base portion 1 where semiconductor elements 2a and 2b are not mounted. In the present embodiment, the reinforcing members 7 are joined to the bottom surface of the base portion 1 along the long side of the base portion 1. Thereby, the similar effect as the effect of the second embodiment can be obtained.

### Fourth Embodiment

FIG. 9 is a top view showing a semiconductor package according to the fourth embodiment of the present invention. Reinforcing members 7 are joined to the region of the base portion 1 where semiconductor elements 2a and 2b are not mounted. In the present embodiment, the reinforcing members 7 are joined to the top surface of the base portion 1 along the long side of the base portion 1. Thereby, the similar effect as the effect of the second embodiment can be obtained.

### Fifth Embodiment

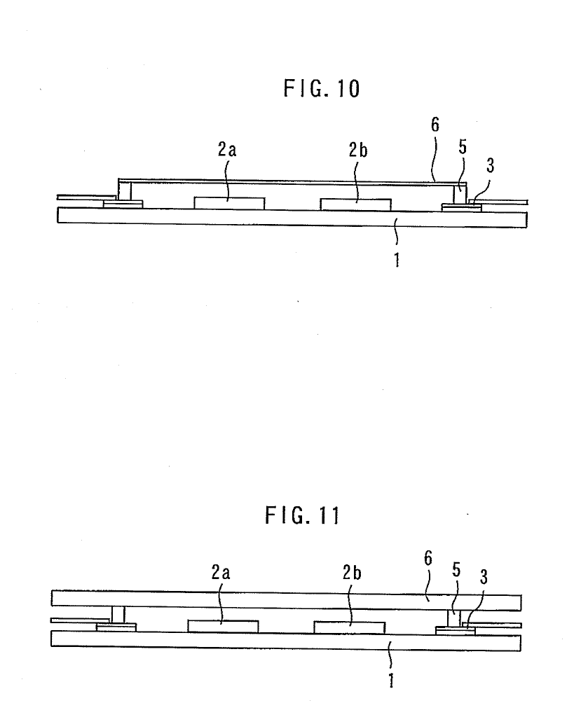

FIG. 10 is a sectional view showing a semiconductor package according to the fifth embodiment of the present invention. In the present embodiment, the cap 6 is composed of kovar or CuW having a low linear expansion coefficient. Therefore, the cap 6 has a linear expansion coefficient lower than the linear expansion coefficient of the base portion 1. By thus reinforcing the cap 6, the warpage of the base portion 1 with thermal history can be prevented. Furthermore, by mounting semiconductor elements 2a and 2b on the base portion 1 having a low thermal resistance, heat dissipation properties can also be secured.

### Sixth Embodiment

FIG. 11 is a sectional view showing a semiconductor package according to the sixth embodiment of the present invention. In the present embodiment, the cap 6 has the same material and the same shape as the base portion 1. By thus reinforcing the cap 6, the warpage of the base portion 1 with thermal history can be prevented. Furthermore, by mounting semiconductor elements 2a and 2b on the base portion 1 having a low thermal resistance, heat dissipation properties can also be secured.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-292998, filed on Dec. 28, 2010 including specification, claims, drawings and summary, on which the Convention priority of the present application is based, are incorporated herein by reference in its entirety.

1. A semiconductor package comprising:
a base portion including a first member and a second member, wherein the first and second members are joined to each other;
a semiconductor element mounted on the first member;
a terminal mounted on the second member; and
a wire electrically connecting the semiconductor element to the terminal, wherein
heat resistance of the first member is lower than heat resistance of the second member, and
linear thermal expansion coefficient of the second member is smaller than linear thermal expansion coefficient of the first member.

2. A semiconductor package comprising:
a base portion;
a semiconductor element mounted on the base portion; and
a reinforcing member joined to a region of the base portion where the semiconductor element is not mounted, wherein
heat resistance of the base portion is lower than heat resistance of the reinforcing member, and
linear thermal expansion coefficient of the reinforcing member is smaller than linear thermal expansion coefficient of the base portion.

3. The semiconductor package according to claim 2, wherein the reinforcing member is joined to a bottom surface of the base portion and surrounds a region of the base portion where the semiconductor element is mounted.

4. The semiconductor package according to claim 2, wherein the base portion is rectangular and has short and long sides, and the reinforcing member is joined to a top surface or a bottom surface of the base portion, along one of the long sides.

5. A semiconductor package comprising:
a base portion;
a semiconductor element mounted on the base portion;
a side-wall member on the base portion and surrounding the semiconductor element; and
a cap joined to the side-wall member and covering the semiconductor element, wherein linear thermal expansion coefficient of the cap is smaller than linear thermal expansion coefficient of the base portion.

6. A semiconductor package comprising:
a base portion;
a semiconductor element mounted on the base portion;
a side-wall member on the base portion and surrounding the semiconductor element; and
a cap joined to the side-wall member and covering the semiconductor element, wherein the cap and the base portion are made of the same material and have the same shape.
